(19) United States
(12) Patent Application Publication
(10) Pub. No.: US 2025/0105111 A1
(43) Pub. Date: Mar. 27, 2025

(54) SEMICONDUCTOR DEVICE

(71) Applicant: MEDIATEK INC., Hsinchu City (TW)

(72) Inventor: Nan-Jang Chen, Hsinchu City (TW)

(21) Appl. No.: 18/892,608

(22) Filed: Sep. 23, 2024

Related U.S. Application Data
(60) Provisional application No. 63/584,515, filed on Sep. 22, 2023.

(51) Int. Cl. H01L 23/498; H01F 17/00; H02H 9/04; H05K 1/02

(52) U.S. Cl. CPC H01L 23/49811; H01F 17/0006; H01L 23/49838; H05K 1/025; H01F 2017/0073; H02H 9/046; H05K 2201/1003

(57) ABSTRACT

A semiconductor device is provided. The semiconductor device includes a first conductive layer and second conductive layer. The second conductive layer is disposed opposite to the first conductive layer. One of the first conductive layer and the second conductive layer includes a first grounding net and a first signal ball-pad. The first grounding net has a first ground void, and the first signal ball-pad is disposed in the first ground void. The first signal ball-pad has a first ball-pad diameter, the first ground void has a first ground void diameter, and a ratio of the first ground void diameter to the first ball-pad diameter is equal to or greater than 1.2.

This application claims the benefit of U.S. provisional application Ser. No. 63/584,515, filed Sep. 22, 2023, the subject matter of which is incorporated herein by reference.

### BACKGROUND OF THE INVENTION

### Field of the Invention

The invention relates in general to a semiconductor device.

### Description of the Related Art

Interfaces with discontinuous impedances will produce signal reflections. The impedance mismatch will lead to signal reflection and attenuation, which is manifested in reverse signal transmission, signal attenuation, and signal distortion. If there is an impedance mismatch at one end of the transmission line, part of the signal will be reflected back. This will affect the power transfer and signal quality of the signal in the transmission line, and also cause echo interference.

### SUMMARY OF THE INVENTION

According to an embodiment of the present disclosure, a semiconductor device is provided. The semiconductor device includes a first conductive layer and second conductive layer. The second conductive layer is disposed opposite to the first conductive layer. One of the first conductive layer and the second conductive layer includes a first grounding net and a first signal ball-pad. The first grounding net has a first void, and the first signal ball-pad is disposed in the first void. The first signal ball-pad has a first pad diameter, the first void has a first ground void diameter, and a ratio of the first ground void diameter to the first pad diameter is equal to or greater than 1.2.

According to another embodiment of the present disclosure, a semiconductor device is provided. The semiconductor device includes a first conductive layer and second conductive layer. The second conductive layer is disposed opposite to the first conductive layer. One of the first conductive layer and the second conductive layer includes a first grounding net and a first signal ball-pad. The first signal ball-pad has a first ball-pad diameter, the first signal ball-pad is spaced from a lateral wall of the first void by a first minimum interval, and the first minimum interval is greater than 0.1 times of the first ball-pad diameter.

The above and other aspects of the disclosure will become better understood with regard to the following detailed description of the preferred but non-limiting embodiment (s). The following description is made with reference to the accompanying drawings.

### BRIEF DESCRIPTION OF THE DRAWINGS

FIG. 1 illustrates a schematic diagram of a semiconductor device according to an embodiment of the present disclosure;

FIG. 2A illustrates a schematic diagram of a first conductive layer of the semiconductor device in FIG. 1;

FIG. 2B illustrates a schematic diagram of a second conductive layer of the semiconductor device in FIG. 1;

FIG. 2C illustrates a schematic diagram of the first conductive layer in FIG. 2A and the second conductive layer in FIG. 2B overlapping;

FIG. 2D illustrates a schematic diagram of a cross-sectional view of the structure in FIG. 2C along a direction 2D-2D′;

FIG. 2E illustrates a schematic diagram of a cross-sectional view of the structure in FIG. 2C along a direction 2E-2E′;

FIG. 3 illustrates a schematic diagram of a relationship between time vs. voltage of groups 1 to 5 in Table 1;

FIG. 4 illustrates a schematic diagram of a first conductive layer according to another embodiment of the present disclosure;

FIG. 5 illustrates a schematic diagram of a top view of a semiconductor device 300 according to another embodiment of the present disclosure;

FIG. 6A illustrates a schematic diagram of a T-coil circuit according to an embodiment of the present disclosure;

FIG. 6B illustrates a schematic diagram of a coil of the T-coil circuit in FIG. 6A;

FIG. 7 illustrates a schematic diagram of a T-coil circuit 20 according to another embodiment of the present disclosure; and

FIG. 8 illustrates a schematic diagram of a semiconductor system 1 according to another embodiment of the present disclosure.

### DETAILED DESCRIPTION OF THE INVENTION

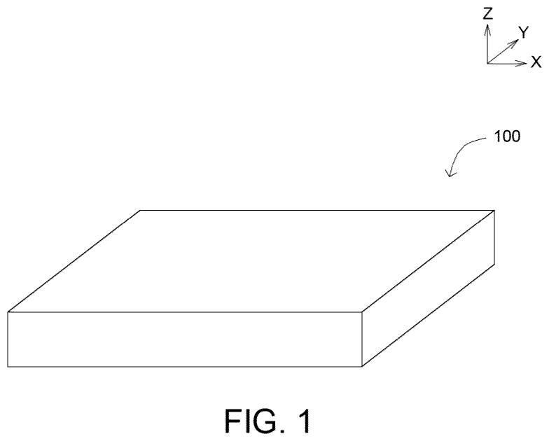

Referring to FIG. 1, FIG. 1 illustrates a schematic diagram of a semiconductor device 100 according to an embodiment of the present disclosure. The semiconductor device 100 is, for example, a semiconductor chip, a silicon interposer, a substrate, a semiconductor package, a circuit board (for example, a printed circuit board), etc. The semiconductor device 100 includes at least one conductive layer, wherein the conductive layer may reduce a capacitance for increasing an impedance (for example, a differential impedance). For example, the differential impedance may be increased from 50 ohm (Ω) to 85Ω, depending on the signal ball-pad dimensions.

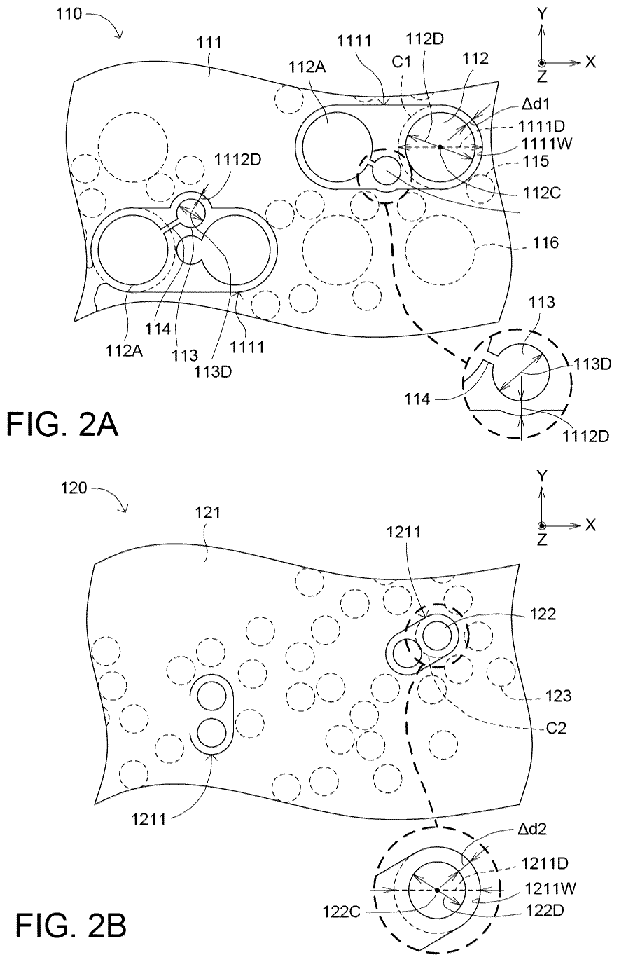

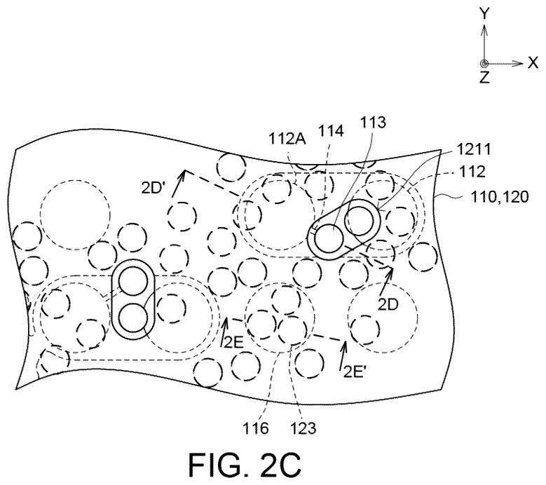

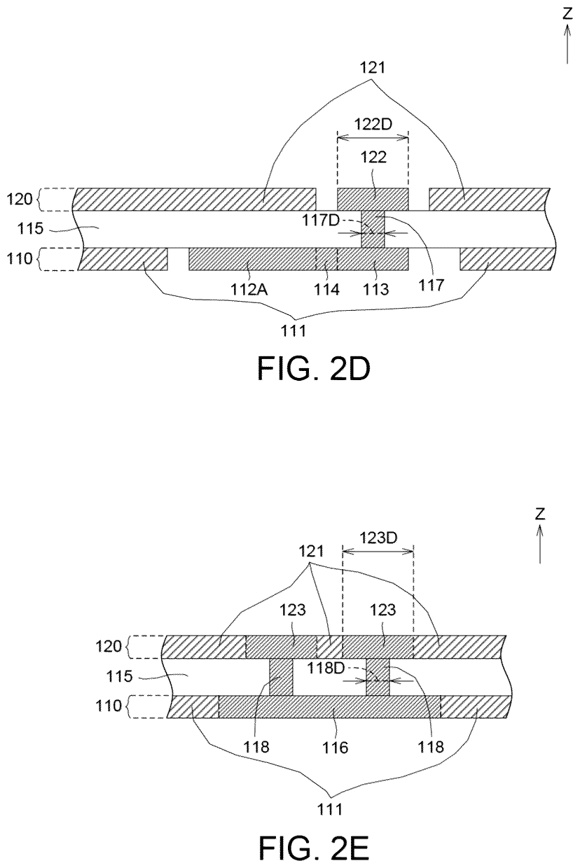

Referring to FIGS. 2A to 2E, FIG. 2A illustrates a schematic diagram of a first conductive layer of the semiconductor device 100 in FIG. 1, FIG. 2B illustrates a schematic diagram of a second conductive layer of the semiconductor device 100 in FIG. 1, FIG. 2C illustrates a schematic diagram of the first conductive layer 110 in FIG. 2A and the second conductive layer 120 in FIG. 2B overlapping, FIG. 2D illustrates a schematic diagram of a cross-sectional view of the structure in FIG. 2C along a direction 2D-2D′, and FIG. 2E illustrates a schematic diagram of a cross-sectional view of the structure in FIG. 2C along a direction 2E-2E′.

As illustrated in FIG. 2A, the first conductive layer 110 includes a first grounding net 111, at least one first signal ball-pad 112, at least one first signal via-pad 113, at least one first signal trace 114, at least one first grounding via-pad 115 and at least one first grounding ball-pad 116.

As illustrated in FIG. 2A, the first grounding net 111 has a first ground void 1111. At least one the first signal ball-pad 112 is disposed within the first ground void 1111, where there is no conductive material existing in the void region to connect the signal pad and grounding net. The first signal ball-pad 112 has a first ball-pad diameter 112D, and the first ground void 1111 has a first ground void diameter 1111D, wherein a ratio of the first ground void diameter 1111D to the first ball-pad diameter 112D is equal to or greater than 1.2, for example. As a result, the capacitance between the first signal ball-pad 112 and the first grounding net 111 may be reduced for increasing the impedance. For example, the differential impedance may be increased from 50 ohm (Ω) to 85Ω, depending on the signal ball-pad dimensions. The first ground void diameter 1111D is a diameter of an approximate circle C1 as close to a lateral wall 1111W of the first ground void 1111 as possible. The approximate circle C1 surrounds the first signal ball-pad 112, and a circle center of the approximate circle C1 overlap a center 112C of the first signal ball-pad 112, for example.

In an embodiment, the first signal ball-pad 112 is spaced from a lateral wall 1111W of the first ground void 1111 by a first minimum interval Δd1, and the first minimum interval Δd1 is greater than 0.1 times of the first ball-pad diameter 112D (that is, Δd1≥0.1×112D). As a result, the capacitance between the first signal ball-pad 112 and the first grounding net 111 may be reduced for increasing the impedance.

As shown in formula (1) below, Z_{diff} is the differential impedance, Cₛ is a self-capacitance, Cₘ is a mutual capacitance, Lₛ is a self-inductance, and Lₘ is a mutual inductance. According to formula (1), the differential impedance Z_{diff} is proportional to the capacitance. In other words, when the capacitance between the first signal ball-pad 112 and the first grounding net 111 reduces, the impedance is increased. Through the ratio design of the conductive layer in the present embodiment, it may achieve the continuous impedance with less reflection.

$${Z}_{diff} = 2 \times \sqrt{\frac{{L}_{S} - {L}_{m}}{{C}_{S} ∓ {C}_{m}}} \qquad ( 1 )$$

As illustrated in FIG. 2A, the first conductive layer 110 is, for example, the bottom conductive layer (for example, the bottommost conductive layer) of the semiconductor device 100. The first signal ball-pad 112 may be exposed from the semiconductor device 100 for connecting a signal contact, for example, a solder ball, solder paste, a bump, a pillar, etc. The first signal via-pad 113, the first signal trace 114 and a second signal ball-pad 112A may be disposed within the first void 1111, wherein the first signal trace 114 connects the second signal ball-pad 112A with the first signal via-pad 113. The first grounding via-pad 115 may connect a grounding via (not illustrated in FIG. 2A). The first grounding ball-pad 116 may be exposed from the semiconductor device 100 for connecting a grounding contact, for example, a solder ball, solder paste, a bump, a pillar, etc. The first signal via-pad 113 has a first via-pad diameter 113D, and the first ground void 1111 has a second ground void diameter 1112D, wherein a ratio of the second ground void diameter 1112D to the first via-pad diameter 113D is equal to or greater than 1.2, for example. As a result, the capacitance between the first signal via-pad 113 and the first grounding net 111 may be reduced for increasing the impedance.

In an embodiment, the first and second signal ball-pads 112 and 112A, the first signal via-pad 113 and the first signal trace 114 may be for used as signal transmission set or signal receiving set. In an embodiment, the first conductive layer 110 may include at least one signal transmission set and/or at least one signal receiving set.

As illustrated in FIG. 2B, in an embodiment, the second conductive layer 120 is disposed above the first conductive layer 110. The second conductive layer 120 includes a second grounding net 121, at least one second signal via-pad 122 and at least one second grounding via-pad 123.

As illustrated in FIG. 2B, the second grounding net 121 has a second ground void 1211, wherein the second signal via-pad 122 is disposed within the second ground void 1211. The second ground void 1211 has a third ground void diameter 1211D, the second signal via-pad 122 has a second via-pad diameter 122D, and a ratio of the third ground void diameter 1211D to the second via-pad diameter 122D is equal to or greater than 1.2, for example. As a result, the capacitance between the second grounding net 121 and the second signal via-pad 122 may reduce for increasing the impedance. The second via-pad diameter 122D is a diameter of an approximate circle C2 as close to a lateral wall 1211W of the second ground void 1211 as possible. The approximate circle C2 surrounds the second signal via-pad 122, and a circle center of the approximate circle C2 overlap a center 122C of the second signal via-pad 122, for example.

In an embodiment, the second signal via-pad 122 is spaced from the lateral wall 1211W of the second ground void 1211 by a second minimum interval Δd2, and the second minimum interval Δd2 is greater than 0.1 times of the second via-pad diameter 122D (that is, Δd2≥0.1×122D). As a result, the capacitance between the second signal via-pad 122 and the second grounding net 121 may be reduced for increasing the impedance.

In an embodiment, a ratio of the third ground void diameter 1211D (as illustrated in FIG. 2B) of the second ground void 1211 in the second conductive layer 120 to the first ball-pad diameter 112D (as illustrated in FIG. 2A) of the first signal ball-pad 112 in the first conductive layer 110 may be greater than 1.0. For example, the first ball-pad diameter 112D would be 280 μm or 240 μm. The second via-pad diameter 122D would be 50 μm, 80 μm, 100 μm, or 120 μm depending on the dimension of semiconductor device.

As illustrated in FIGS. 2C and 2D, the second conductive layer 120 may be disposed above the first conductive layer 110. Two adjacent conductive layers may be separated by a dielectric layer. For example, the second conductive layer 120 and the first conductive layer 110 may be separated by a dielectric layer 115. The second conductive layer 120 may be electrically connected with the first conductive layer 110 by at least one signal via 117. Furthermore, the signal via 117 connects the second signal via-pad 122 in the second conductive layer 120 with the first signal via-pad 113 in the first conductive layer 110. The signal via 117 has a via diameter 117D, and a ratio of the via diameter 117D to the second via-pad diameter 122D may equal to 0.5, even less or greater. For example, the via diameter 117D is, for example, 50 micrometers (μm), and the second via-pad diameter 122D is, for example, 100 μm.

As illustrated in FIGS. 2B and 2C, the first ball-pad diameter 112D is greater than the second via-pad diameter 122D. As a result, the first signal ball-pad 112 may provide a larger area for receiving the signal contact, for example, a solder ball, solder paste, a bump, a pillar, etc.

As illustrated in FIGS. 2C and 2E, the second conductive layer 120 may be electrically connected with the first conductive layer 110 by at least one grounding via 118. Furthermore, the grounding via 118 connects the second grounding via-pad 123 in the second conductive layer 120 with the first grounding ball-pad 116 in the first conductive layer 110. The grounding via 118 has a via diameter 118D, and the second grounding ball-pad 123 has a second pad diameter 123D, wherein a ratio of the via diameter 118D to the second pad diameter 123D may equal to 0.5, even less or greater. For example, the via diameter 118D is, for example, 50 micrometers (μm), and the second pad diameter 123D is, for example, 100 μm.

As illustrated in FIG. 2C, in an embodiment, at least one portion of the second ground void 1211 overlap at least one portion of the first signal ball-pad 112 in Z-axis, and accordingly it may reduce the capacitance for increasing the impedance.

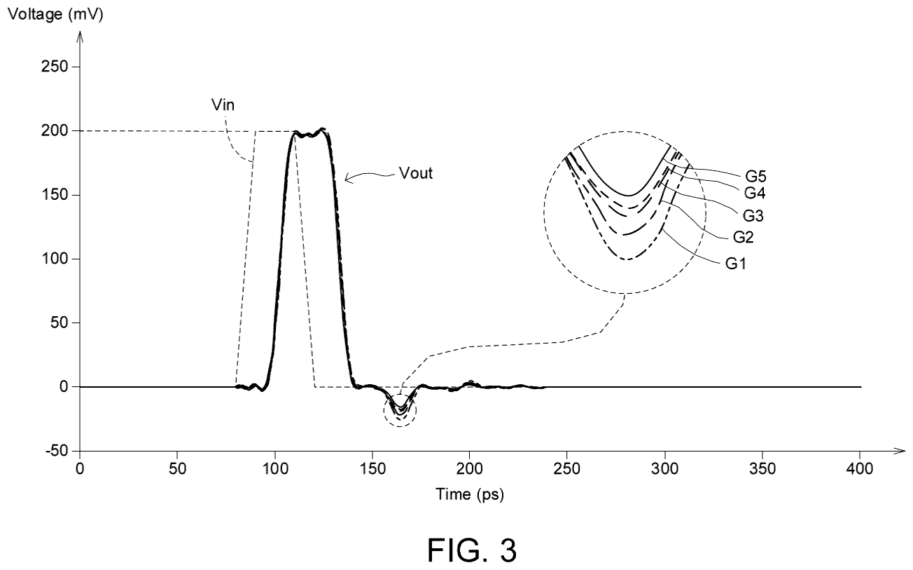

Referring to FIG. 3, FIG. 3 illustrates a schematic diagram of a relationship between time vs. voltage of groups 1 to 5 in Table 1. The relationship between time vs. voltage may be obtained by using SBR (single-bit response) simulation. In group 1, there are two conductive layers (Layer 3 and Layer 4) use the design of the ratio as started above, wherein a ground void diameter of at least one void in Layer 4 is 290 μm, and a ground void diameter of at least one void in Layer 3 is 240 μm. In group 2, there are three conductive layers (Layer 2, Layer 3 and Layer 4) use the design of the ratio as started above, wherein a ground void diameter of at least one void in Layer 4 is 290 μm, a ground void diameter of at least one void in Layer 3 is 290 μm, and a ground void diameter of at least one void in Layer 2 is 290 μm. In group 3, there are four conductive layers (Layer 1, Layer 2, Layer 3 and Layer 4) use the design of the ratio as started above, wherein a ground void diameter of at least one void in Layer 4 is 290 μm, a ground void diameter of at least one void in Layer 3 is 290 μm, a ground void diameter of at least one void in Layer 2 is 290 μm and a ground void diameter of at least one void in Layer 1 is 290 μm. In group 4, there are four conductive layers (Layer 1, Layer 2, Layer 3 and Layer 4) use the design of the ratio as started above, wherein a ground void diameter of at least one void in Layer 4 is 340 μm, a ground void diameter of at least one void in Layer 3 is 290 μm, a ground void diameter of at least one void in Layer 2 is 290 μm and a ground void diameter of at least one void in Layer 1 is 290 μm. In group 5, there are four conductive layers (Layer 1, Layer 2, Layer 3 and Layer 4) use the design of the ratio as started above, wherein a ground void diameter of at least one void in Layer 4 is 390 μm, a ground void diameter of at least one void in Layer 3 is 290 μm, a ground void diameter of at least one void in Layer 2 is 290 μm and a ground void diameter of at least one void in Layer 1 is 290 μm. The Layer 4 in group 5 has the greater the ground void diameter than that of Layer 4 in group 4. The Layer 4 is, for example, the bottommost conductive layer of the semiconductor device, and Layers 4 to 1 are disposed in order from bottom to top.

TABLE 1

ground void diameter (μm)

| Group | Layer 1 | Layer 2 | Layer 3 | Layer 4 |
|---|---|---|---|---|
| 1 | Retain | Retain | 240 | 290 |
| 2 | Retain | 290 | 290 | 290 |
| 3 | 290 | 290 | 290 | 290 |
| 4 | 290 | 290 | 290 | 340 |
| 5 | 290 | 290 | 290 | 390 |

As illustrated in FIG. 3, the curves G1 to G5 present the output voltage Vout from the first signal ball-pad 112 (for example, in Layer 4) in groups 1 to 5 respectively. The input pulsed voltage Vin is input to a contact (for example, bump) of a chip, through the trace and connecting to the signal ball-pad (not illustrated) which may be disposed outside the semiconductor device 100 or inside the semiconductor device 100. The input pulsed voltage Vin is 0.2 v with 42.8 picosecond (ps) of one unit interval (UI), 10 ps of rise time and 10 ps of fall time, for example. The first reflections of groups 1 to 5 are shown in an enlarged diagram of FIG. 3.

As illustrated in FIG. 3, the less the signal reflection, the better the impedance continuity is. The curve G5 presents the minimum signal reflection, and the curve G1 presents the maximum signal reflection. A ratio of the curve G1 to the curve G5 in 1^{st} reflection is −37.7% (for example, calculation formula:

$$1 - \frac{- 24.7 - ( - 15.4 ) mV}{- 24.7 mV} ) .$$

It can be seen that the impedance continuity may be obviously improved by the size or ration design of the ground void and the signal ball-pad as stated above.

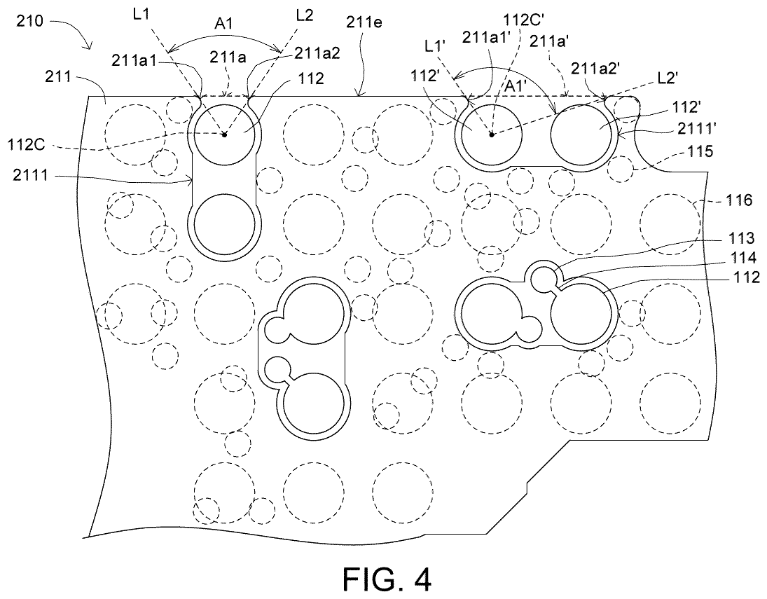

Referring to FIG. 4, FIG. 4 illustrates a schematic diagram of a first conductive layer 210 according to another embodiment of the present disclosure. The first conductive layer 210 may replace the first conductive layer 110 in FIG. 2A. The first conductive layer 210 includes a first grounding net 211, at least one first signal ball-pad 112, at least one first signal via-pad 113, at least one first signal trace 114, at least one first grounding via-pad 115 and at least one first grounding ball-pad 116. The first grounding net 211 has a boundary 211e, wherein the first void 2111 extends to the boundary 211e to form an opening 211a. In the present embodiment, the opening 211a exposes one first signal ball-pad 112. There is a first connection line L1 of the center 112C of the first signal ball-pad 112 and a first edge 211a1 of the opening 211a, and There is a second connection line L2 of the center 112C of the first signal ball-pad 112 and a second edge 211 a2 of the opening 211a, wherein an angle A1 included between the first connection line L1 and the second connection line L2 may be equal to or greater than 60 degrees. As a result, the first conductive layer 210 may reduce the capacitance for increasing the impedance (for example, the differential impedance). For example, the impedance may be increased from 68Ω to 73Ω.

As illustrated in FIG. 4, the first ground void 2111′ exposes an opening 211a′. In the present embodiment, the opening 211a′ exposes a plurality of the first signal ball-pad 112′. There is a first connection line L1′ of the center 112C′ of the first signal ball-pad 112′ and a first edge 211a1′ of the opening 211a′, and there is a second connection line L2′ of the center 112C′ of the first signal ball-pad 112′ and a second edge 211a2′ of the opening 211a′, wherein an angle A1′ included between the first connection line L1′ and the second connection line L2′ may be equal to or greater than 60 degrees. As a result, the first conductive layer 210 may reduce the capacitance for increasing the impedance (for example, the differential impedance). For example, the impedance may be increased from 68Ω to 73Ω.

In another embodiment, the first ground void 2111 having the opening 211a and the opening 211a′ may be applied to the first grounding net 111 in FIG. 2A.

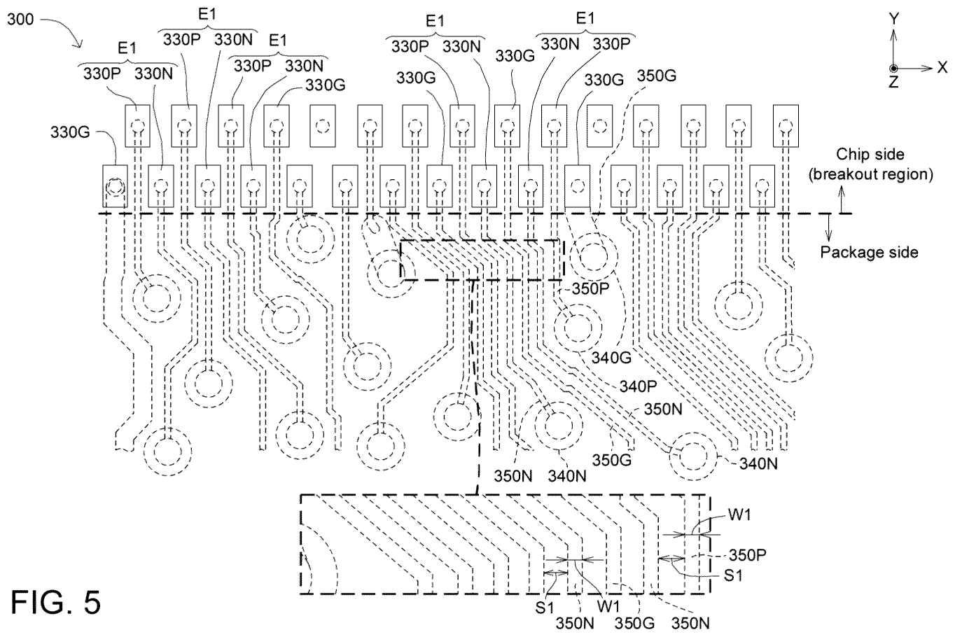

Referring to FIG. 5, FIG. 5 illustrates a schematic diagram of a top view of a semiconductor device 300 according to another embodiment of the present disclosure. The semiconductor device 300 includes a chip and a package, and the chip may be stacked to the package.

As illustrated in FIG. 5, the chip includes a plurality of grounding contacts 330G, a plurality of negative electrode contacts 330N and a plurality of positive electrode contacts 330P. One electrode contact 330N and the positive electrode contact 330P construct one electrode set E1. In an embodiment, in a region, one electrode set E1 may be located between two grounding contacts 330G, and in another region, a plurality of the electrode sets E1 may be located between two grounding contacts 330G.

As illustrated in FIG. 5, the package includes a plurality of grounding contacts 340G, a plurality of negative electrode contacts 340N and a plurality of positive electrode contacts 340P, a plurality of grounding traces 350G, a plurality of negative electrode traces 350N and a plurality of positive electrode traces 350P.

As illustrated in FIG. 5, the grounding trace 350G connects the grounding contact 330G through the grounding contacts 340G. The negative electrode trace 350N connects the negative electrode contact 330N through the negative electrode contact 340N. The positive electrode trace 350P connects the positive electrode contact 330P through the positive electrode contact 340P. In an embodiment, the trace may be a SerDes (Serializer/Deserializer) trace.

As illustrated in FIG. 5, in the present embodiment, the positive electrode contact 330P and the negative electrode contact 330N are staggered to each other in a first direction and a second direction different from the first direction, wherein the first direction is, for example, parallel to X-axis, and the second direction is, for example, parallel to Y-axis. As a result, the chip size can be reduced with the staggered electrode contacts.

As illustrated in FIG. 5, each trace has a trace width W1, and the trace widths W1 are substantially equal in the breakout region and out of breakout region as shown in FIG. 5, for example. There is a trace space S1 between two adjacent traces, wherein the trace spaces S1 are substantially equal, for example. The substantially equal trace widths W1 and/or the substantially equal spaces S1 may achieve the continuous impedance with less reflection.

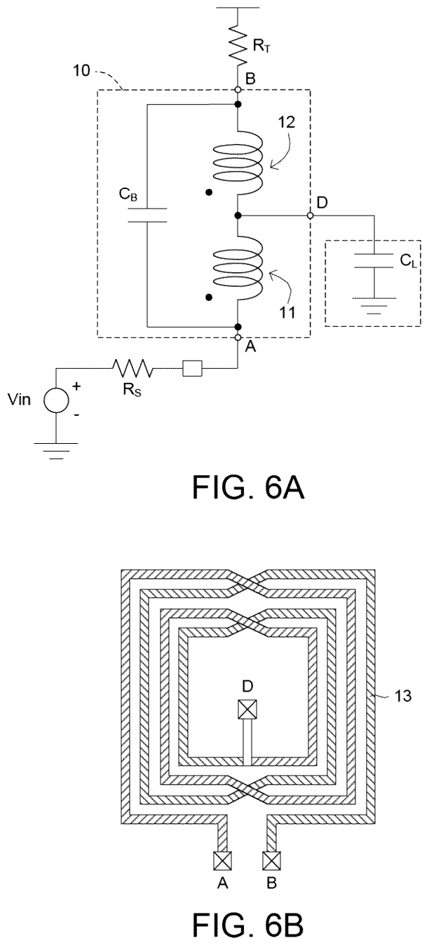

Referring to FIGS. 6A and 6B, FIG. 6A illustrates a schematic diagram of a T-coil circuit 10 according to an embodiment of the present disclosure, and FIG. 6B illustrates a schematic diagram of a coil 13 of the T-coil circuit 10 in FIG. 6A. The T-coil circuit 10 may be disposed in the chip to counteract the effects of parasitic capacitances (C_{L}) including electrostatic discharge (ESD) protection circuits, input/output (1/O) pads, and others.

As illustrated in FIG. 6A, the T-coil circuit 10 includes a first inductor 11 and a second inductor 12, wherein a first inductance value L₁ of the first inductor 11 and a second inductance value L₂ of the second inductor 12 satisfy the following formulas (2a) to (2b). In formulas (2a) to (2b), ζ is a damping factor of a transfer function, C_{L} is a load capacitance, CB is a bridge capacitor, and R_{T} is a termination resistance.

$${L}_{1} = {L}_{2} = \frac{{C}_{L} {R}_{T}^{2}}{4} ( 1 + \frac{1}{4 {ζ}^{2}} ) \qquad ( 2 a )$$

$${C}_{B} = \frac{{C}_{L}}{16 {ζ}^{2}} \qquad ( 2 b )$$

As illustrated in FIGS. 6A and 6B, a coil 13 forming the first inductor 11 and the second inductor 12 may spirally extend from a first terminal A to a second terminal B, wherein a third terminal D connects a line between the first inductor 11 and the second inductor 12 with the load capacitance C_{L}.

The T-coil circuit 10 is a special form of an inductive peaking circuit that will extend an amplifier's bandwidth and speed up the output signal rise-time. The circuit uses a coupled inductor and a small bridging capacitor. The T-coil circuit 10 may double the bandwidth of an amplifier. The inductor as steers an input current into the load capacitance C_{L}, so it charges up more rapidly. The small bridging capacitor ensures that the input impedance of the T-coil is constant and resistive.

As shown in Table 2 below, the impedance Zin is equal to a termination resistance R_{T}, and the inductance value of the coil 13 is proportional to value of R_{T}² (or proportional to the impedance Zin). The less the termination resistance R_{T} is, the less the occupied area of the coil 13 is. In other words, compared to the differential impedance (=2R_{T}) being 100Ω, the occupied area of the coil 13 is less when the differential impedance (=2R_{T}) being 80Ω (for example, reduced by 36%).

TABLE 2

| R_{T} = Zᵢₙ (Ω) | R_{T}² | L (nH) | ratio |
|---|---|---|---|
| 60.0 | 3,600 | 1.44 | 44% |
| 50.0 | 2,500 | 1.00 | 0 |
| 45.0 | 2,025 | 0.81 | −19% |
| 42.5 | 1,806 | 0.72 | −28% |
| 40.0 | 1,600 | 0.64 | −36% |
| 37.5 | 1,406 | 0.56 | −44% |
| 35.0 | 1,225 | 0.49 | −51% |

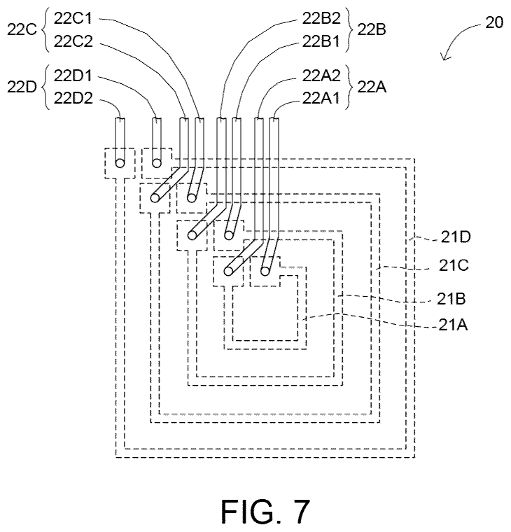

Referring to FIG. 7, FIG. 7 illustrates a schematic diagram of a T-coil circuit 20 according to another embodiment of the present disclosure. The T-coil circuit 20 may be disposed in or on a chip, a silicon interposer, a substrate, a package or a circuit board.

As illustrated in FIG. 7, the T-coil circuit 20 includes a first coil 21A, a second coil 21B, a third coil 21C and a fourth coil 21D, a first conductive trace set 22A, a second conductive trace set 22B, a third conductive trace set 22C and a fourth conductive trace set 22D. The first conductive trace set 22A includes a first trace 22A1 and a second trace 22A2, and the first trace 22A1 and the second trace 22A2 are connected with two terminal of the first coil 21A. The second conductive trace set 22B includes a first trace 22B1 and a second trace 22B2, and the first trace 22B1 and the second trace 22B2 are connected with two terminal of the second coil 21B. The third conductive trace set 22C includes a first trace 22C1 and a second trace 22C2, and the first trace 22C1 and the second trace 22C2 are connected with two terminal of the third coil 21C. The fourth conductive trace set 22D includes a first trace 22D1 and a second trace 22D2, and the first trace 22D1 and the second trace 22D2 are connected with two terminal of the fourth coil 21D.

As illustrated in FIG. 7, the first conductive trace set 22A may be electrically connected with the first coil 21A through a first controller (not illustrated). The second conductive trace set 22B may be electrically connected with the second coil 21B through a second controller (not illustrated). The third conductive trace set 22C may be electrically connected with the third coil 21C through a third controller (not illustrated). The fourth conductive trace set 22D may be electrically connected with the fourth coil 21D through a fourth controller (not illustrated). The first controller, the second controller, the third controller and the fourth controller include, for example, MUX/Selector or MOS switch.

In the present embodiment, like using at least one bond wire (not illustrated) to adjust spiral inductors (namely, the first coil 21A, the second coil 21B, the third coil 21C and the fourth coil 21D) in the package (for example, a BGA package), the segmented spiral inductors in the T-coil network would be selected through at least one controller (including, for example, MUX/Selector or MOS switch) to match the dedicated termination (R_{T}) or compensate the process variation.

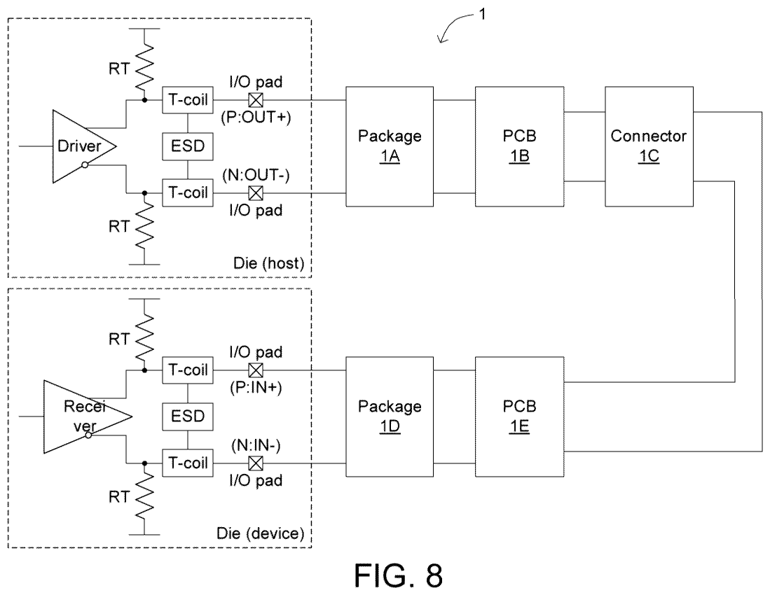

Referring to FIG. 8, FIG. 8 illustrates a schematic diagram of a semiconductor system 1 according to another embodiment of the present disclosure. The semiconductor system 1 includes a package 1A, a package 1B, a connector 1C, a PCB 1D, a PCB 1E, a driver and a receiver. The driver may transmit a signal to the receiver through the T-coil, the package 1A, the PCB 1B, the connector 1C, the PCB 1E, the package 1D and the T-coil. The ESD component is equivalent to a larger capacitor, and the T-coil is electrically connected with the ESD component and may provide a inductance for impedance matching. In addition, the aforementioned ratio design of the conductive layer may be applied to the package 1A, the PCB 1B, the package 1D, the PCB 1E, etc.

In summary, the embodiment of the present invention provides a semiconductor device. The semiconductor device includes at least two conductive layers, wherein at least one of the conductive layers includes a grounding net and at least one signal ball-pad, and the grounding net has at least one ground void in the signal ball-pad is disposed. The signal ball-pad has a ball-pad diameter, the ground void has a ground void diameter, and a ratio of the ground void diameter to the ball-pad diameter is equal to or greater than 1.2. As a result, the capacitance between the signal ball-pad and the grounding net may be reduced for increasing the impedance and impedance continuity.

While the disclosure has been described by way of example and in terms of the preferred embodiment (s), it is to be understood that the disclosure is not limited thereto. Based on the technical features embodiments of the present disclosure, a person ordinarily skilled in the art will be able to make various modifications and similar arrangements and procedures without breaching the spirit and scope of protection of the disclosure. Therefore, the scope of protection of the present disclosure should be accorded with what is defined in the appended claims.

What is claimed is:

1. A semiconductor device, comprising:
a first conductive layer, and
a second conductive layer disposed opposite to the first conductive layer;
wherein the first conductive layer comprises:
a first grounding net having a first ground void; and
a first signal ball-pad in the first ground void;
wherein the first signal ball-pad has a first ball-pad diameter, the first ground void has a first ground void diameter, and a ratio of the first ground void diameter to the first ball-pad diameter is equal to or greater than 1.2.

2. The semiconductor device according to claim 1, wherein the first conductive layer is a bottom layer, the first signal ball-pad of the bottom layer is configured for connecting a contact.

3. The semiconductor device according to claim 1, wherein the first conductive layer comprises:
a first signal via-pad within the first ground void;
wherein the first ground void has a second ground void diameter, the first signal via-pad has a first via-pad diameter, and a ratio of the second ground void diameter to the first via-pad diameter is equal to or greater than 1.2.

4. The semiconductor device according to claim 1, wherein the second conductive layer is disposed above the first conductive layer, the second conductive layer comprises:
a second grounding net having a second ground void; and
a second signal via-pad within the second ground void;
wherein the second ground void has a third ground void diameter, the second signal via-pad has a second via-pad diameter, and a ratio of the third ground void diameter to the second via-pad diameter is equal to or greater than 1.2.

5. The semiconductor device according to claim 3, wherein the first ball-pad diameter is greater than the first via-pad diameter.

6. The semiconductor device according to claim 4, wherein the first signal ball-pad at least partially overlaps the second ground void in a stack direction of the first conductive layer and the second conductive layer.

7. The semiconductor device according to claim 4, wherein the second ground void diameter is greater than the first ball-pad diameter.

8. The semiconductor device according to claim 1, wherein the first grounding net has a boundary, the first ground void extends to the boundary to form an opening, and the opening exposes the first signal ball-pad.

9. The semiconductor device according to claim 8, wherein there is a first connection line of a center of the first signal ball-pad and a first edge of the opening, and there is a second connection line of the center of the first signal ball-pad and a second edge of the opening, wherein an angle included between the first connection line and the second connection line is equal to or greater than 60 degrees.

10. A semiconductor device, comprising:
a first conductive layer, and
a second conductive layer opposite to the first conductive layer;
wherein the first conductive layer comprises:
a first grounding net having a first ground void; and
a first signal ball-pad in the first ground void;
wherein the first signal ball-pad has a first ball-pad diameter, the first signal ball-pad is spaced from a lateral wall of the first ground void by a first minimum interval, and the first minimum interval is greater than 0.1 times of the first ball-pad diameter.

11. The semiconductor device according to claim 10, wherein the first conductive layer is a bottom layer, the first signal ball-pad of the bottom layer is configured for connecting a contact.

12. The semiconductor device according to claim 10, wherein the second conductive layer is disposed above the first conductive layer, the second conductive layer comprises:
a second grounding net having a second ground void; and
a second signal via-pad within the second ground void;
wherein the second signal via-pad has a second via-pad diameter, the second signal via-pad is spaced from a lateral wall of the second ground void by a second minimum interval, and the second minimum interval is greater than 0.1 times of the second via-pad diameter.

13. The semiconductor device according to claim 12, wherein the first signal ball-pad has a first ball-pad diameter, and the first ball-pad diameter is greater than the first via-pad diameter.

14. The semiconductor device according to claim 12, wherein the first signal ball-pad at least partially overlaps the second ground void in a stack direction of the first conductive layer and the second conductive layer.

15. The semiconductor device according to claim 12, wherein the first signal ball-pad has a first ball-pad diameter, and the second ground void has a second ground void diameter, wherein the second ground void diameter is greater than the first ball-pad diameter.

16. The semiconductor device according to claim 10, wherein the first grounding net has a boundary, the first void extends to the boundary to form an opening, and the opening exposes the first signal ball-pad.

17. The semiconductor device according to claim 16, wherein there is a first connection line of a center of the first signal ball-pad and a first edge of the opening, and there is a second connection line of the center of the first signal ball-pad and a second edge of the opening, wherein an angle included between the first connection line and the second connection line is equal to or greater than 60 degrees.
